(19) United States
(12) Patent Application Publication
(10) Pub. No.: US 2026/0261262 A1
(43) Pub. Date: Sep. 3, 2026

(54) GATE DRIVER CIRCUIT, MOTOR DRIVE DEVICE USING SAME, AND ELECTRONIC DEVICE

(71) Applicant: ROHM CO., LTD., Kyoto (JP)

(72) Inventor: Hisashi SUGIE, Kyoto (JP)

(21) Appl. No.: 19/546,607

(22) Filed: Feb. 23, 2026

(30) Foreign Application Priority Data
Feb. 28, 2025 (JP) 2025-031839

(51) Int. Cl. H03K 17/687; H02P 27/08

(52) U.S. Cl. CPC H03K 17/6871; H02P 27/08; H03K 2217/0063; H03K 2217/0072

(57) ABSTRACT

A gate driver circuit includes: a first input terminal configured to receive a high-side input signal indicating on and off of a high-side transistor in a first mode; a second input terminal configured to receive a low-side input signal indicating on and off of a low-side transistor in the first mode; a logic circuit configured to convert a pair of the high-side input signal and the low-side input signal into a pair of an internal enable signal and an internal pulse modulated signal; a low-pass filter configured to receive the internal enable signal and the internal pulse modulated signal and generate an output enable signal and an output pulse modulated signal; and a control circuit configured to receive the output enable signal and the output pulse modulated signal and control a high-side driver and a low-side driver based on a dead time zero control.

### CROSS REFERENCE TO RELATED APPLICATION

The present invention claims priority under 35 U.S.C. § 119 to Japanese Patent Application No. 2025-031839, filed on Feb. 28, 2025, the entire contents of which are incorporated herein by reference.

### TECHNICAL FIELD

The present disclosure relates to a gate driver circuit.

### BACKGROUND

A half-bridge circuit, an H-bridge circuit, and a three-phase bridge circuit (hereinafter, collectively referred to as a “switching circuit”), which use power transistors, are used in a motor driver circuit, a DC/DC converter, a power conversion device, and the like.

The switching circuit includes a bridge circuit (inverter circuit) including high-side and low-side transistors, and a gate driver circuit that drives the high-side and low-side transistors. The switching circuit controls the high-side and low-side transistors in response to control signals from an external controller such as a microcontroller or an application specific integrated circuit (ASIC).

Input interfaces of a gate driver circuit may be broadly classified into two types. One type of interface, like a three-state buffer, controls on/off states of a high-side transistor MH and a low-side transistor ML by using a control signal that combines an enable signal EN and a pulse modulated signal PWM. A truth table for this interface is as follows.

(EN, PWM)⇒(MH, ML)
(0, 0)⇒(OFF, OFF)
(0, 1)⇒(OFF, OFF)
(1, 0)⇒(OFF, ON)
(1, 1)⇒(ON, OFF)

The interface described above is called an EN-PWM type interface.

The other type of interface directly indicates on/off states of the high-side transistor MH and the low-side transistor ML by using two control signals HIN and LIN. A truth table for this interface is as follows.

(HIN, LIN)⇒(MH, ML)
(0,0)⇒(OFF, OFF)
(0,1)⇒(OFF, ON)
(1,0)⇒(ON, OFF)
(1,1)⇒(OFF, OFF)

The interface described above is called an IN-IN type interface.

### BRIEF DESCRIPTION OF DRAWINGS

The accompanying drawings, which are incorporated in and constitute a part of the specification, illustrate embodiments of the present disclosure.

FIG. 1 is a circuit diagram of a switching circuit including a gate driver circuit according to a comparative technique.

FIG. 2 is a time chart explaining a dead time zero control of the switching circuit shown in FIG. 1.

FIG. 3 is a diagram explaining an operation of the switching circuit shown in FIG. 1.

FIG. 4 is a circuit diagram of a switching circuit including a gate driver circuit according to an embodiment.

FIG. 5 is a time chart explaining an operation of the gate driver circuit shown in FIG. 4.

FIG. 6 is a circuit diagram of a gate driver circuit according to a first modification.

FIG. 7 is a circuit diagram of a gate driver circuit according to a second modification.

FIG. 8 is a circuit diagram of a gate driver circuit according to a third modification.

FIG. 9 is a circuit diagram of a motor drive device according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview of Embodiments

An overview of some exemplary embodiments of the present disclosure will be described. This overview is intended to provide a simplified description of some concepts of one or more embodiments in order to provide a basic understanding of the embodiments as a prelude to the following detailed description, and is not intended to limit the breadth of the disclosure. For the sake of convenience, “one embodiment” may be used to refer to an embodiment (an example or a modification) or multiple embodiments (examples or modifications) disclosed in the present specification.

This overview is not a comprehensive overview of all possible embodiments, and is not intended to specify key elements of all embodiments or delineate the scope of some or all modes. A sole purpose of this overview is to present some concepts of one or more embodiments in a simplified form as a prelude to more detailed description that is presented later.

A gate driver circuit according to one embodiment drives a high-side transistor and a low-side transistor that constitute a switching circuit. The gate driver circuit includes: a first input terminal configured to receive a high-side input signal indicating on and off of the high-side transistor in a first mode; a second input terminal configured to receive a low-side input signal indicating on and off of the low-side transistor in the first mode; a logic circuit configured to convert a pair of the high-side input signal and the low-side input signal into a pair of an internal enable signal and an internal pulse modulated signal; a low-pass filter configured to receive the internal enable signal and the internal pulse modulated signal and generate an output enable signal and an output pulse modulated signal; a high-side driver configured to drive the high-side transistor; a low-side driver configured to drive the low-side transistor; and a control circuit configured to receive the output enable signal and the output pulse modulated signal and control the high-side driver and the low-side driver based on a dead time zero control.

With this configuration, IN-IN type input signals are converted into EN-PWM type signals in the gate driver circuit, and the enable signal and the pulse modulated signal are subjected to a low-pass filtering, so that a short negation of the enable signal is masked. Therefore, it is possible to suppress generation of unintended short high-impedance periods.

In one embodiment, the gate driver circuit may further include a high-side turn-off detection circuit configured to assert a high-side off detection signal upon detecting that the high-side transistor is turned off based on a gate signal of the high-side driver, and a low-side turn-off detection circuit configured to assert a low-side off detection signal upon detecting that the low-side transistor is turned off based on a gate signal of the low-side driver. The control circuit may perform the dead time zero control by using the high-side off detection signal and the low-side off detection signal.

In one embodiment, the first input terminal may be further configured to receive, in a second mode, one of an input pulse modulated signal indicating an output level of the switching circuit and an input enable signal indicating whether or not an output of the switching circuit is at a high impedance. The second input terminal may be further configured to receive, in the second mode, the other of the input pulse modulated signal and the input enable signal. The low-pass filter may be invalidated in the second mode. The gate driver circuit may further include: a first selector configured to receive the internal enable signal and the input enable signal, and configured to select and supply the internal enable signal to the low-pass filter in the first mode and select and supply the input enable signal to the low-pass filter in the second mode; and a second selector configured to receive the internal pulse modulated signal and the input pulse modulated signal, and configured to select and supply the internal pulse modulated signal to the low-pass filter in the first mode and select and supply the input pulse modulated signal to the low-pass filter in the second mode.

With this configuration, it is possible to use the gate driver circuit in combination with any one of an external controller having an IN-IN type output interface and an external controller having an EN-PWM type output interface.

In one embodiment, the first input terminal may be further configured to receive, in a second mode, one of an input pulse modulated signal indicating an output level of the switching circuit and an input enable signal indicating whether or not an output of the switching circuit is at a high impedance. The second input terminal may be further configured to receive, in the second mode, the other of the input pulse modulated signal and the input enable signal. The gate driver circuit may further include: a first selector configured to receive the output enable signal and the input enable signal, and configured to select and supply the output enable signal to the low-pass filter in the first mode and select and supply the input enable signal to the low-pass filter in the second mode; and a second selector configured to receive the output pulse modulated signal and the input pulse modulated signal, and configured to select and supply the output pulse modulated signal to the low-pass filter in the first mode and select and supply the input pulse modulated signal to the low-pass filter in the second mode.

With this configuration, it is possible to use the gate driver circuit in combination with any one of an external controller having an IN-IN type output interface and an external controller having an EN-PWM type output interface.

In one embodiment, the gate driver circuit may be monolithically integrated on a single semiconductor substrate. The term “monolithically integrated” includes both cases where all circuit components are formed on the semiconductor substrate and where main circuit components are monolithically integrated. Some resistors, capacitors, and the like may be provided outside the semiconductor substrate to adjust circuit constants. By integrating the circuit on a single chip, it is possible to reduce a circuit area and to maintain characteristics of circuit elements uniform.

A motor drive device according to one embodiment may include a bridge circuit including a high-side transistor and a low-side transistor, and one of the above-described gate driver circuit that drives the high-side transistor and the low-side transistor.

An electronic device according to one embodiment may include a motor, and the above-described motor drive device that drives the motor.

### EMBODIMENTS

Some embodiments will be described below with reference to the drawings. Identical or equivalent components, parts, and processes shown in each drawing are denoted by same reference numerals, and redundant descriptions thereof will be omitted appropriately. Further, the embodiments are exemplary and are not intended to limit the present disclosure. All features and combinations thereof described in the embodiments are not necessarily essential to the present disclosure.

In the present disclosure, “a state where a member A is connected to a member B” includes a case where the member A and the member B are physically directly connected or even a case where the member A and the member B are indirectly connected via any other member that does not substantially affect an electrical connection state between the members A and B or does not impair functions and effects achieved by combinations of the members A and B.

Similarly, “a state where a member C is provided between a member A and a member B” includes a case where the member A and the member C or the member B and the member C are indirectly connected via any other member that does not substantially affect an electrical connection state between the members A and C or the members B and C or does not impair functions and effects achieved by combinations of the members A and C or the members B and C, in addition to a case where the member A and the member C or the member B and the member C are directly connected.

Before describing a gate driver circuit according to one embodiment, a gate driver circuit according to a comparative technique will be described.

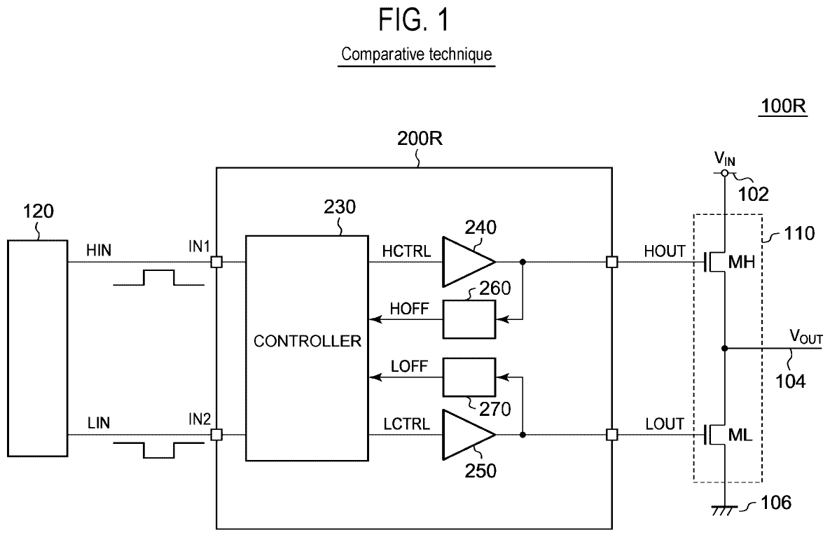

FIG. 1 is a circuit diagram of a switching circuit 100R including a gate driver circuit 200R according to the comparative technique. The switching circuit 100R includes a bridge circuit 110, an external controller 120, and the gate driver circuit 200R. While only a configuration for a single phase of the switching circuit 100R is shown here, the switching circuit 100R may also be a three-phase circuit or an H-bridge circuit.

The bridge circuit 110 includes a high-side transistor MH provided between an input line (power supply line) 102 and an output line 104, and a low-side transistor ML provided between the output line 104 and a ground line 106. An input voltage V_{IN} is applied to the input line 102. The high-side transistor MH and the low-side transistor ML are N-channel MOSFETs.

The gate driver circuit 200R has an IN-IN type input interface. A high-side input signal HIN indicating on and off of the high-side transistor MH is input from the external controller 120 to a first input terminal IN1 of the gate driver circuit 200R, and a low-side input signal LIN indicating on and off of the low-side transistor ML is input from the external controller 120 to a second input terminal IN2 of the gate driver circuit 200R.

The gate driver circuit 200R turns the high-side transistor MH off when the high-side input signal HIN at the first input terminal IN1 is at a first level (e.g., low), and turns the high-side transistor MH on when the high-side input signal HIN is at a second level (e.g., high). The gate driver circuit 200R turns the low-side transistor ML off when the low-side input signal LIN at the second input terminal IN2 is at the first level (e.g., low), and turns the low-side transistor ML on when the low-side input signal LIN is at the second level (e.g., high).

The gate driver circuit 200R includes a controller 230, a high-side driver 240, a low-side driver 250, a high-side off sensor 260, and a low-side off sensor 270.

The controller 230 generates a high-side control signal HCTRL indicating on and off of the high-side transistor MH in response to the high-side input signal HIN at the first input terminal IN1. In addition, the controller 230 generates a low-side control signal LCTRL indicating on and off of the low-side transistor ML in response to the low-side input signal LIN at the second input terminal IN2. The controller 230 performs a dead time zero control so that a dead time period (high impedance period) during which the high-side transistor MH and the low-side transistor ML are simultaneously turned off is made infinitesimally short.

When transitioning from a high output state (V_{OUT}=V_{IN}) in which the high-side transistor MH is turned on and the low-side transistor ML is turned off to a low output state (V_{OUT}=0 V) in which the high-side transistor MH is turned off and the low-side transistor ML is turned on, a gate signal HOUT of the high-side transistor MH is lowered first. Then, when the high-side transistor MH is turned off, a gate signal LOUT of the low-side transistor ML begins to rise.

The high-side off sensor 260 monitors the gate signal (gate-source voltage) of the high-side transistor MH, and asserts a high-side off detection signal HOFF (e.g., high) upon detecting that the high-side transistor MH is turned off. In response to the assertion of the high-side off detection signal HOFF, the controller 230 starts an operation of the low-side driver 250 to turn the low-side transistor ML on.

Conversely, when transitioning from the low output state (V_{OUT}=0 V) in which the high-side transistor MH is turned off and the low-side transistor ML is turned on to the high output state (V_{OUT}=V_{IN}) in which the high-side transistor MH is turned on and the low-side transistor ML is turned off, the gate signal LOUT of the low-side transistor ML is lowered first. Then, when the low-side transistor ML is turned off, the gate signal HOUT of the high-side transistor MH begins to rise.

The low-side off sensor 270 monitors the gate signal (gate-source voltage) of the low-side transistor ML, and asserts a low-side off detection signal LOFF (e.g., high) upon detecting that the low-side transistor ML is turned off. In response to the assertion of the low-side off detection signal LOFF, the controller 230 starts an operation of the high-side driver 240 to turn on the high-side transistor MH.

A configuration of the switching circuit 100R has been described above. Next, an operation of the switching circuit 100R will be described.

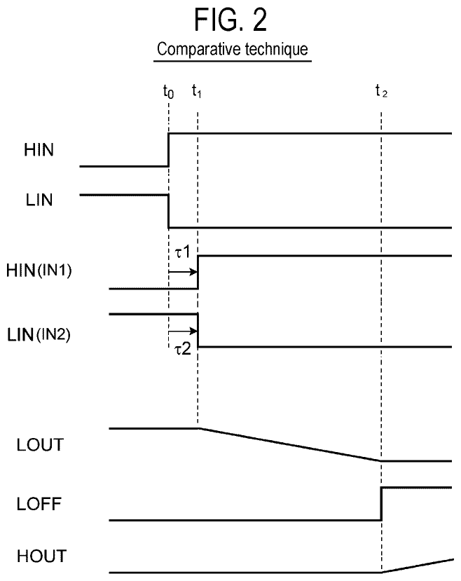

FIG. 2 is a time chart explaining a dead time zero control of the switching circuit 100R shown in FIG. 1. At time t₀, the low-side input signal LIN and the high-side input signal HIN at output terminals of the external controller 120 transition substantially at the same time in a complementary manner.

The high-side input signal HIN and the low-side input signal LIN are input to the gate driver circuit 200R from the external controller 120 via two wirings. When delays τ1 and τ2 of the two wirings are equal to each other, the high-side input signal HIN(IN1) at the first input terminal IN1 and the low-side input signal LIN(IN2) at the second input terminal IN2 transition simultaneously at time t₁, which is a timing after the wiring delay has elapsed from time t₀.

When the low-side input signal LIN (IN2) transitions to a low level at time t₁, the controller 230 generates the low-side control signal LCTRL so that the gate signal LOUT of the low-side transistor ML decreases. At time t₁, the low-side driver 250 starts operating, and the gate signal LOUT begins to decrease.

At time t₂, when the gate signal LOUT decreases to a predetermined threshold voltage, the low-side off detection signal LOFF is asserted. In response to the assertion of the low-side off detection signal LOFF, the controller 230 generates the high-side control signal HCTRL so that the gate signal HOUT of the high-side transistor MH rises.

As described above, immediately after the low-side transistor ML is turned off, the high-side transistor MH is turned on. Thus, a length of a high-impedance period becomes substantially zero.

Next, problems that arise in the switching circuit 100R shown in FIG. 1 will be described.

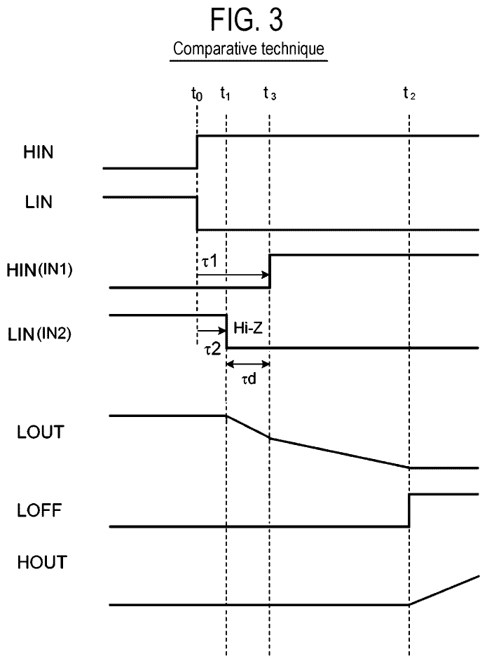

FIG. 3 is a diagram explaining an operation of the switching circuit 100R shown in FIG. 1. The high-side input signal HIN and the low-side input signal LIN are input from the external controller 120 to the gate driver circuit 200R via two wires. A case is considered where there is a difference τd between propagation delays τ1 and τ2 of the two wires. At time t₁, which is a timing after the delay time τ2 has elapsed from time t₀, the low-side input signal LIN(IN2) at the second input terminal IN2 transitions to a low level. At time t₃, which is a timing after the delay time τ1 has elapsed from time t₀, the high-side input signal HIN(IN1) at the first input terminal IN1 transitions to a high level.

That is, even though the external controller 120 generates the control signals HIN and LIN such that the dead time becomes zero, the gate driver circuit 200R is instructed to be in a high impedance state during a period from time t₁ to time t₃.

An operation of the gate driver circuit 200R in the high-impedance state is not particularly limited. In this example, during the period in which the gate driver circuit 200R is instructed to be in the high-impedance state, the gate signal LOUT is reduced steeply so as to turn the low-side transistor ML off rapidly.

When the gate driver circuit 200R is instructed to be in a high output state at time t₃, the gate signal LOUT is generated so that the low-side transistor ML is turned off at a normal speed.

Thus, in the comparative technique, even though the dead time zero control is performed, a narrow high impedance period is inserted due to an influence of the delay time τd.

Hereinafter, a technique for solving the problems that arise in the comparative technique will be described.

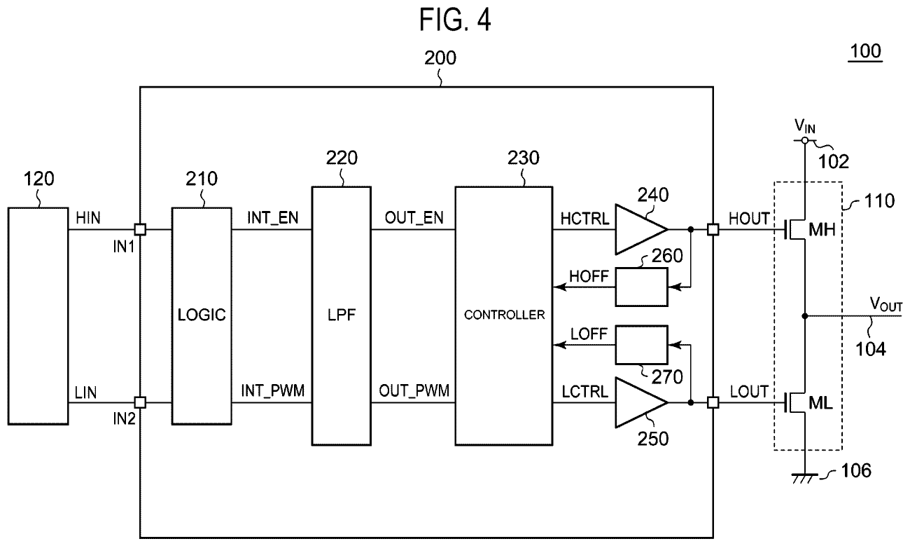

FIG. 4 is a circuit diagram of a switching circuit 100 including a gate driver circuit 200 according to an embodiment. The gate driver circuit 200 includes a logic circuit 210, a low-pass filter 220, a controller 230, a high-side driver 240, a low-side driver 250, a high-side off sensor 260, and a low-side off sensor 270, and is integrated on a single semiconductor substrate.

A high-side input signal HIN indicating on and off of a high-side transistor MH is input to a first input terminal IN1 of the gate driver circuit 200. A low-side input signal LIN indicating on and off of a low-side transistor ML is input to a second input terminal IN2.

The logic circuit 210 converts the high-side input signal HIN and the low-side input signal LIN into an internal enable signal INT_EN and an internal PWM signal INT_PWM. The internal enable signal INT_EN is a signal corresponding to an EN-PWM type enable signal EN. When the internal enable signal INT_EN is at a first level corresponding to assertion, a bridge circuit 110 is in a high output state or a low output state, and when the internal enable signal INT_EN is at a second level corresponding to negation (de-assertion), the output of the bridge circuit 110 is in a high impedance state. The internal PWM signal INT_PWM is an EN-PWM type pulse modulated signal. When the internal PWM signal INT_PWM is at a first level (e.g., low), the bridge circuit 110 is in a low output state, and when the internal PWM signal INT_PWM is at a second level (e.g., high), the bridge circuit 110 is in a high output state.

A truth table for inputs and outputs of the logic circuit 210 can be defined, for example, as follows.

| Input | Output |
|---|---|
| (HIN, LIN) | (INT_EN, INT_PWM) |
| (0, 0) | (L, H*) |
| (0, 1) | (H, L) |
| (1, 0) | (H, H) |
| (1, 1) | (L, L*) |

Note that * indicates redundancy (Don't Care) and may be either H or L.

The low-pass filter 220 receives the internal enable signal INT_EN and the internal PWM signal INT_PWM and removes high-frequency components from each of them. Specifically, cutoff frequencies of the low-pass filter 220 are set to values that can remove narrow pulses of about several nanoseconds, for example, pulse widths narrower than 10 ns, which appear in the internal enable signal INT_EN and the internal PWM signal INT_PWM. The cutoff frequency for the internal enable signal INT_EN and the cutoff frequency for the internal PWM signal INT_PWM may be the same or different from each other.

The controller 230 receives the internal enable signal INT_EN (referred to as an “output enable signal OUT_EN”) after passing through the low-pass filter 220, and the internal PWM signal INT_PWM (referred to as an “output PWM signal OUT_PWM”) after passing through the low-pass filter 220. When the output enable signal OUT_EN is low, the controller 230 controls the high-side driver 240 and the low-side driver 250 so that both of the high-side transistor MH and the low-side transistor ML are turned off.

When the output enable signal OUT_EN is high, the controller 230 controls the high-side driver 240 and the low-side driver 250 based on a dead time zero control so that either the high-side transistor MH or the low-side transistor ML is turned on according to the output PWM signal OUT_PWM.

For the dead time zero control, the high-side off sensor 260 and the low-side off sensor 270 are provided. The high-side off sensor 260 monitors a gate signal (gate-source voltage) of the high-side transistor MH, and asserts a high-side off detection signal HOFF (e.g., high) upon detecting that the high-side transistor MH is turned off. The low-side off sensor 270 monitors a gate signal (gate-source voltage) of the low-side transistor ML, and asserts a low-side off detection signal LOFF (e.g., high) upon detecting that the low-side transistor ML is turned off.

When the output PWM signal OUT_PWM transitions from low to high, the controller 230 controls the low-side driver 250 to turn the low-side transistor ML off. Further, in response to the assertion of the low-side off detection signal LOFF, the controller 230 controls the high-side driver 240 to turn the high-side transistor MH on.

When the output PWM signal OUT_PWM transitions from high to low, the controller 230 controls the high-side driver 240 to turn the high-side transistor MH off. Further, in response to the assertion of the high-side off detection signal HOFF, the controller 230 controls the low-side driver 250 to turn the low-side transistor ML on.

A configuration of the gate driver circuit 200 has been described above. Next, an operation of the gate driver circuit 200 will be described.

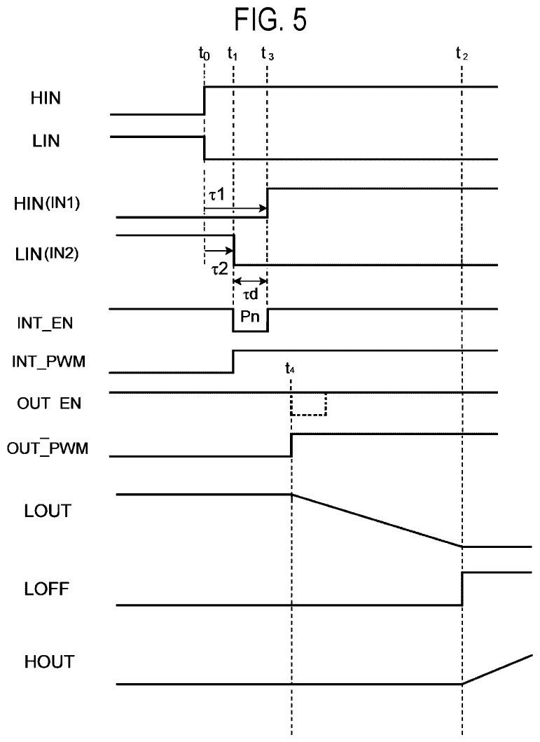

FIG. 5 is a time chart explaining an operation of the gate driver circuit 200 shown in FIG. 4. At time t₁, which is a timing after the delay time τ2 has elapsed from time t₀, the low-side input signal LIN(IN2) of the second input terminal IN2 transitions to a low level. At time t₃, which is a timing after the delay time τ1 has elapsed from time t₀, the high-side input signal HIN(IN1) of the first input terminal IN1 transitions to a high level.

The logic circuit 210 receives the low-side input signal LIN(IN2) and the high-side input signal HIN(IN1) and generates the internal enable signal INT_EN and the internal PWM signal INT_PWM based on the truth table. The internal enable signal INT_EN includes a narrow pulse (negative pulse) Pn that is kept low for a period corresponding to the delay time τd.

Since high frequency components of the internal enable signal INT_EN are removed by the low-pass filter 220, the narrow pulse Pn is removed from the output enable signal OUT_EN.

When the output PWM signal OUT_PWM transitions from low to high at time t₄ after a filter delay time has elapsed, the controller 230 controls the low-side driver 250 to turn the low-side transistor ML off, and decreases the gate signal LOUT.

When the low-side off detection signal LOFF is asserted at time t₂, the controller 230 controls the high-side driver 240 to turn the high-side transistor MH on, and raises the gate signal HOUT.

An operation of the gate driver circuit 200 has been described above. According to the gate driver circuit 200, when the IN-IN type input signals HIN and LIN are input with different delays, it is possible to prevent an output of the bridge circuit 110 from going into a high impedance state, and to maintain the zero dead time control.

### Modifications

Next, modifications of the gate driver circuit 200 will be described.

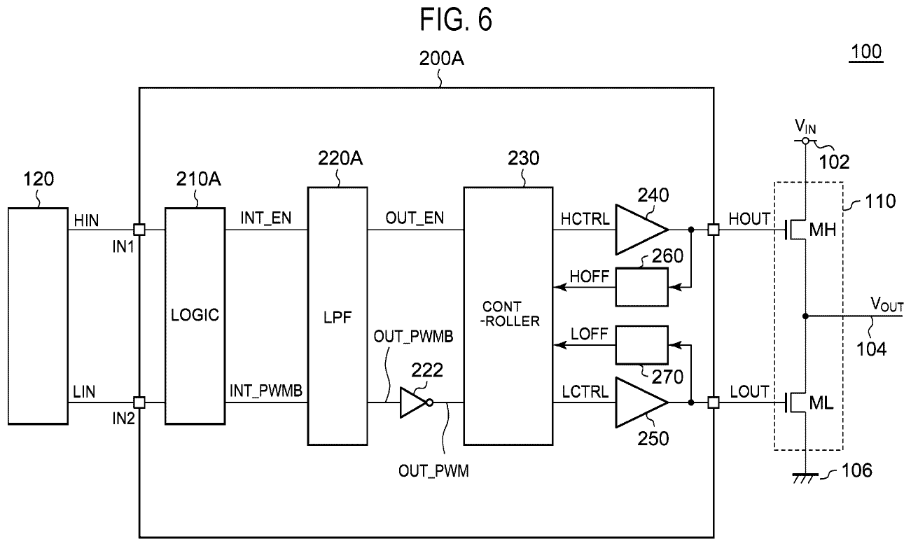

FIG. 6 is a circuit diagram of a gate driver circuit 200A according to a first modification. In this modification, a truth table of a logic circuit 210A is different from the truth table of the logic circuit 210 shown in FIG. 4.

The input/output truth table of the logic circuit 210A can be defined, for example, as follows, and an internal PWM signal INT_PWMB is a negative logic signal.

| Input | Output |
|---|---|
| (HIN, LIN) | (INT_EN, INT_PWMB) |
| (0, 0) | (L, L*) |
| (0, 1) | (H, H) |
| (1, 0) | (H, L) |
| (1, 1) | (L, H*) |

Note that * indicates redundancy (Don't Care) and may be either H or L.

A low-pass filter 220A removes high frequency components from the negative-logic internal PWM signal INT_PWMB to generate a negative-logic output PWM signal OUT_PWMB. An inverter 222 inverts the negative-logic output PWM signal OUT_PWMB to generate a positive-logic output PWM signal OUT_PWM.

As described above, logic values assigned to various digital signals in the gate driver circuit 200 can be changed.

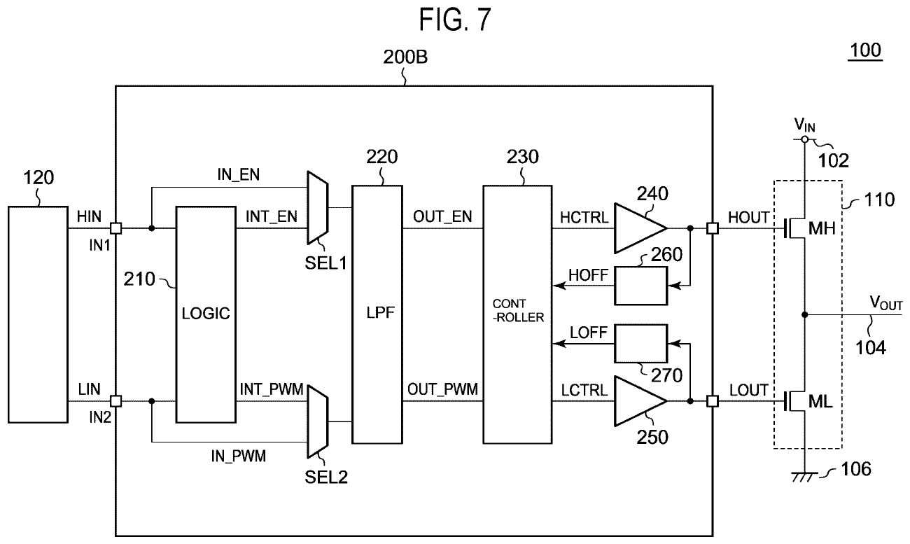

FIG. 7 is a circuit diagram of a gate driver circuit 200B according to a second modification. This gate driver circuit 200B can receive EN-PWM type input signals IN_EN and IN_PWM instead of IN-IN type input signals HIN and LIN. The gate driver circuit 200B is set to a first mode when used in an IN-IN type application circuit, and is set to a second mode when used in an EN-PWM type application circuit.

When the gate driver circuit 200B is used in the EN-PWM type application circuit, a function of the logic circuit 210 is bypassed. Specifically, the gate driver circuit 200B includes a first selector SEL1 and a second selector SEL2.

The first selector SEL1 receives an internal enable signal INT_EN and the input enable signal IN_EN. The first selector SEL1 selects the internal enable signal INT_EN in the first mode, and selects the input enable signal IN_EN in the second mode.

The second selector SEL2 receives an internal PWM signal INT_PWM and the input PWM signal IN_PWM. The second selector SEL2 selects the internal PWM signal INT_PWM in the first mode, and selects the input PWM signal IN_PWM in the second mode.

In the second mode, a low-pass filter 220 may be invalidated.

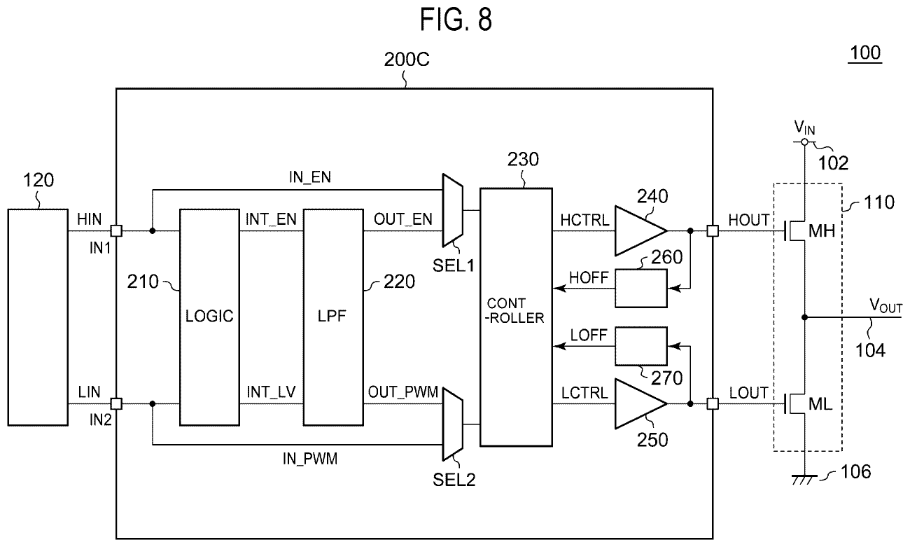

FIG. 8 is a circuit diagram of a gate driver circuit 200C according to a third modification. As in FIG. 7 (the second modification), the gate driver circuit 200C supports the EN-PWM type and IN-IN type interfaces, and when the gate driver circuit 200C is used in an EN-PWM type application circuit, a function of the logic circuit 210 is bypassed. The gate driver circuit 200C includes a first selector SEL1 and a second selector SEL2, but positions of the first selector SEL1 and the second selector SEL2 are different from the positions of the first selector SEL1 and the second selector SEL2 shown in FIG. 7.

The first selector SEL1 receives an output enable signal OUT_EN and an input enable signal IN_EN. In a first mode, the first selector SEL1 selects the output enable signal OUT_EN and outputs it to a controller 230. In a second mode, the first selector SEL1 selects the input enable signal IN_EN and outputs it to the controller 230.

The second selector SEL2 receives an output PWM signal OUT_PWM and an input PWM signal IN_PWM. In the first mode, the second selector SEL2 selects the output PWM signal OUT_PWM and outputs it to the controller 230. In the second mode, the second selector SEL2 selects the input PWM signal IN_PWM and outputs it to the controller 230.

### Applications

Next, applications of the switching circuit 100 will be described. The switching circuit 100 can be used appropriately in a motor drive circuit.

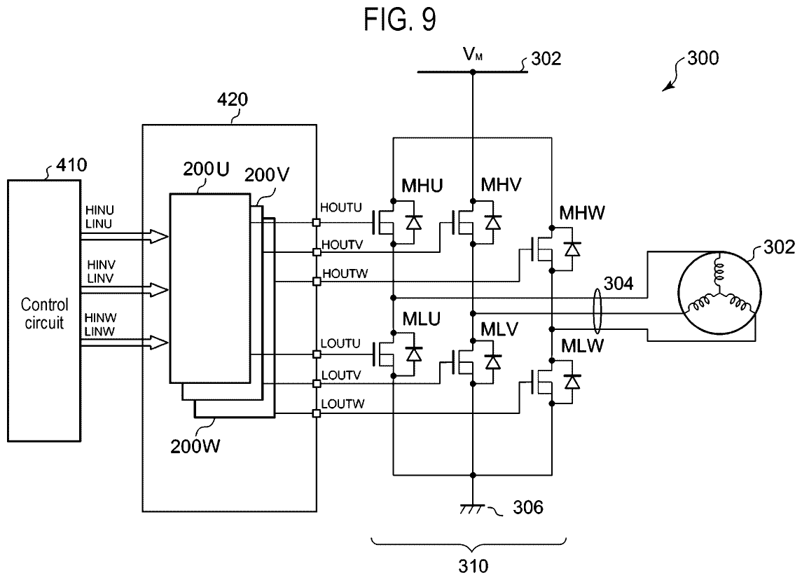

FIG. 9 is a circuit diagram of a motor drive device 300 according to an embodiment. The motor drive device 300 drives a three-phase motor 302, which is a load, and controls a rotation state of the three-phase motor 302.

The motor drive device 300 includes a bridge circuit 310, a control circuit 410, and a three-phase gate driver circuit 420. The bridge circuit 310 is a three-phase inverter and has U-phase, V-phase, and W-phase legs. Further, each phase leg includes a high-side transistor MH and a low-side transistor ML.

The three-phase gate driver circuit 420 includes gate driver circuits 200U, 200V, and 200W for U-phase, V-phase, and W-phase, respectively. The gate driver circuits 200U, 200V, and 200W are configured with the architecture described above. The control circuit 410 generates control signals indicating states of the legs (switching circuits) for the U-phase, V-phase, and W-phase, respectively, based on a state of the three-phase motor 302 as a load, and supplies the control signals to the three-phase gate driver circuit 420.

Although the three-phase motor has been described as an example here, the motor may also be a single-phase motor. In this case, the bridge circuit 310 is an H-bridge circuit.

Next, applications of the motor drive device 300 will be described. The motor drive device 300 may be used to control a spindle motor of a hard disk or a lens drive motor of an imaging device. Further, the motor drive device 300 may be used to drive a printer head drive motor or a paper feed motor. Furthermore, the motor drive device 300 may be used to drive motors in electric vehicles, hybrid vehicles, and the like.

The embodiments are merely examples. It will be understood by those skilled in the art that various modifications may be made by combining individual components and individual processing steps, and that such modifications are also within the scope of the present disclosure. Hereinafter, such modifications will be described.

### Modification 1

In the embodiments, the bridge circuit 110 is configured as a discrete component, but the present disclosure is not limited thereto. The bridge circuit 110 may be integrated into the gate driver circuit 200.

### Modification 2

The power transistors may be configured as insulated gate bipolar transistors (IGBTs).

### Modification 3

The application of the switching circuit 100 is not limited to the motor drive device 300. For example, the switching circuit 100 may be used appropriately in switching regulators (DC/DC converters), various power conversion devices (inverters and converters), inverters for lighting discharge lamps, digital audio amplifiers, and the like. Therefore, the switching circuit 100 may be used in consumer devices including electronic devices and home appliances, automobiles, in-vehicle components, industrial vehicles, and industrial machinery.

### Modification 4

The method and configuration of the dead time zero control performed by the controller 230 are not limited to those using the high-side off sensor 260 and low-side off sensor 270 described in the embodiments. For example, the dead time zero control may be performed by predicting a turn-off timing of a high-side transistor or a low-side transistor by a timer, or other methods may be used.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

### Supplementary Notes

The following techniques are disclosed in the present specification.

### Item 1

A gate driver circuit for driving a high-side transistor and a low-side transistor that constitute a switching circuit, the gate driver circuit including:
a first input terminal configured to receive a high-side input signal indicating on and off of the high-side transistor in a first mode;
a second input terminal configured to receive a low-side input signal indicating on and off of the low-side transistor in the first mode;
a logic circuit configured to convert a pair of the high-side input signal and the low-side input signal into a pair of an internal enable signal and an internal pulse modulated signal;
a low-pass filter configured to receive the internal enable signal and the internal pulse modulated signal and generate an output enable signal and an output pulse modulated signal;
a high-side driver configured to drive the high-side transistor;
a low-side driver configured to drive the low-side transistor; and
a control circuit configured to receive the output enable signal and the output pulse modulated signal and control the high-side driver and the low-side driver based on a dead time zero control.

### Item 2

The gate driver circuit of Item 1, further including:
a high-side turn-off detection circuit configured to assert a high-side off detection signal upon detecting that the high-side transistor is turned off based on a gate signal of the high-side driver; and
a low-side turn-off detection circuit configured to assert a low-side off detection signal upon detecting that the low-side transistor is turned off based on a gate signal of the low-side driver,
wherein the control circuit performs the dead time zero control by using the high-side off detection signal and the low-side off detection signal.

### Item 3

The gate driver circuit of Item 1 or 2, wherein the first input terminal is further configured to receive, in a second mode, one of an input pulse modulated signal indicating an output level of the switching circuit and an input enable signal indicating whether or not an output of the switching circuit is at a high impedance,
wherein the second input terminal is further configured to receive, in the second mode, the other of the input pulse modulated signal and the input enable signal,
wherein the low-pass filter is invalidated in the second mode, and
wherein the gate driver circuit further includes:
   a first selector configured to receive the internal enable signal and the input enable signal, and configured to select and supply the internal enable signal to the low-pass filter in the first mode and select and supply the input enable signal to the low-pass filter in the second mode; and
   a second selector configured to receive the internal pulse modulated signal and the input pulse modulated signal, and configured to select and supply the internal pulse modulated signal to the low-pass filter in the first mode and select and supply the input pulse modulated signal to the low-pass filter in the second mode.

### Item 4

The gate driver circuit of Item 1 or 2, wherein the first input terminal is further configured to receive, in a second mode, one of an input pulse modulated signal indicating an output level of the switching circuit and an input enable signal indicating whether or not an output of the switching circuit is at a high impedance,
wherein the second input terminal is further configured to receive, in the second mode, the other of the input pulse modulated signal and the input enable signal, and
wherein the gate driver circuit further includes:
   a first selector configured to receive the output enable signal and the input enable signal, and configured to select and supply the output enable signal to the low-pass filter in the first mode and select and supply the input enable signal to the low-pass filter in the second mode; and
   a second selector configured to receive the output pulse modulated signal and the input pulse modulated signal, and configured to select and supply the output pulse modulated signal to the low-pass filter in the first mode and select and supply the input pulse modulated signal to the low-pass filter in the second mode.

### Item 5

The gate driver circuit of any one of Items 1 to 4, wherein the gate driver circuit is integrated on a single semiconductor substrate.

### Item 6

A motor drive device, including:
a bridge circuit including a high-side transistor and a low-side transistor; and
the gate driver circuit of any one of Items 1 to 5 that drives the high-side transistor and the low-side transistor.

### Item 7

An electronic device, including:
a motor; and
the motor drive device of Item 6 that drives the motor.

What is claimed is:

1. A gate driver circuit for driving a high-side transistor and a low-side transistor that constitute a switching circuit, the gate driver circuit comprising:
a first input terminal configured to receive a high-side input signal indicating on and off of the high-side transistor in a first mode;
a second input terminal configured to receive a low-side input signal indicating on and off of the low-side transistor in the first mode;
a logic circuit configured to convert a pair of the high-side input signal and the low-side input signal into a pair of an internal enable signal and an internal pulse modulated signal;
a low-pass filter configured to receive the internal enable signal and the internal pulse modulated signal and generate an output enable signal and an output pulse modulated signal;
a high-side driver configured to drive the high-side transistor;
a low-side driver configured to drive the low-side transistor; and
a control circuit configured to receive the output enable signal and the output pulse modulated signal and control the high-side driver and the low-side driver based on a dead time zero control.

2. The gate driver circuit of claim 1, further comprising:
a high-side turn-off detection circuit configured to assert a high-side off detection signal upon detecting that the high-side transistor is turned off based on a gate signal of the high-side driver; and
a low-side turn-off detection circuit configured to assert a low-side off detection signal upon detecting that the low-side transistor is turned off based on a gate signal of the low-side driver,
wherein the control circuit performs the dead time zero control by using the high-side off detection signal and the low-side off detection signal.

3. The gate driver circuit of claim 1, wherein the first input terminal is further configured to receive, in a second mode, one of an input pulse modulated signal indicating an output level of the switching circuit and an input enable signal indicating whether or not an output of the switching circuit is at a high impedance,
wherein the second input terminal is further configured to receive, in the second mode, the other of the input pulse modulated signal and the input enable signal,
wherein the low-pass filter is invalidated in the second mode, and
wherein the gate driver circuit further comprises:
a first selector configured to receive the internal enable signal and the input enable signal, and configured to select and supply the internal enable signal to the low-pass filter in the first mode and select and supply the input enable signal to the low-pass filter in the second mode; and
a second selector configured to receive the internal pulse modulated signal and the input pulse modulated signal, and configured to select and supply the internal pulse modulated signal to the low-pass filter in the first mode and select and supply the input pulse modulated signal to the low-pass filter in the second mode.

4. The gate driver circuit of claim 1, wherein the first input terminal is further configured to receive, in a second mode, one of an input pulse modulated signal indicating an output level of the switching circuit and an input enable signal indicating whether or not an output of the switching circuit is at a high impedance,
wherein the second input terminal is further configured to receive, in the second mode, the other of the input pulse modulated signal and the input enable signal, and
wherein the gate driver circuit further comprises:
a first selector configured to receive the output enable signal and the input enable signal, and configured to select and supply the output enable signal to the low-pass filter in the first mode and select and supply the input enable signal to the low-pass filter in the second mode; and
a second selector configured to receive the output pulse modulated signal and the input pulse modulated signal, and configured to select and supply the output pulse modulated signal to the low-pass filter in the first mode and select and supply the input pulse modulated signal to the low-pass filter in the second mode.

5. The gate driver circuit of claim 1, wherein the gate driver circuit is integrated on a single semiconductor substrate.

6. A motor drive device, comprising:
a bridge circuit including a high-side transistor and a low-side transistor; and
the gate driver circuit of claim 1 that drives the high-side transistor and the low-side transistor.

7. An electronic device, comprising:
a motor; and
the motor drive device of claim 6 that drives the motor.
